(19) United States
(12) Patent Application Publication
(10) Pub. No.: US 2024/0206085 A1
(43) Pub. Date: Jun. 20, 2024

(54) NOVEL TIMER MODULE

(71) Applicant: NINGBO HAPPY ELECTRICAL CO., LTD., Cixi (CN)

(72) Inventor: Yi WEN, Cixi (CN)

(21) Appl. No.: 18/585,723

(22) Filed: Feb. 23, 2024

Related U.S. Application Data
(63) Continuation of application No. 17/649,349, filed on Jan. 29, 2022.

(51) Int. Cl. H05K 5/00; H05K 1/18

(52) U.S. Cl. CPC H05K 5/0069; H05K 1/184; H05K 5/0004; H05K 2201/10053

(57) ABSTRACT

Disclosed is a novel timer module. The novel timer module includes a replaceable movement, a master control circuit board, an upper housing, and a lower housing. A circuit board is disposed inside the replaceable movement. Five first inserting pins are welded on the circuit board. The first inserting pins are exposed from the outside of a housing of the replaceable movement. The master control circuit board is located in the upper housing and the lower housing, and is fixed on an upper surface of the lower housing. A relay is disposed inside the master control circuit board. Contacts of the relay respectively extend and are fixed on a surface of the master control circuit board by using leads. Therefore, a problem that a conventional timer movement is fixedly welded on a circuit of a timer module can be resolved.

### CROSS REFERENCE TO RELATED APPLICATION

This application is a continuation of U.S. application Ser. No. 17/649,349, entitled “Novel timer module,” filed Jan. 29, 2022, and the entire contents of which are incorporated herein by reference.

### TECHNICAL FIELD

The present invention belongs to the technical field of timers, and specifically, to a novel timer module.

### BACKGROUND

The timing movement of the conventional timer module is usually fixed on a circuit in a welding manner. As a result, once the type of the timing movement is determined, the timing function of the entire timer module is determined. However, during actual application, the timing movement is easy to damage. Once the timing movement is damaged, a maintenance cost is expensive. Therefore, in many cases, the entire timer module will be replaced, resulting in a waste of resources. In addition, in a conventional method, once the timing movement is determined, the timing function of the entire timer is determined, so that the timing function cannot be changed.

### SUMMARY

In view of this, in order to resolve a problem that a conventional timer movement is fixedly welded on a circuit of a timer module, the present invention provides a novel timer module. According to the novel timer module, the timer movement is no longer directly welded on the circuit board of the timer module, and a loop of a circuit control portion (that is, a coil power supply) of a relay on a master control circuit board is connected to an inserting slot 32 by using a second inserting pin 31, so that the inserting slot 32 can be raised on a surface of the master control circuit board. In addition, a replaceable movement 1 is disposed. A first inserting pin 11 is disposed on the replaceable movement 1. The first inserting pin 11 is welded on a circuit board inside the replaceable movement 1, and can be inserted into the inserting slot 32. In this way, the replaceable movement can be conducted with the inserting slot 32 in the replaceable movement 1 by using the first inserting pin 11. Therefore, the replaceable movement 1 can control a timing function of the master control circuit board. By using the timer module of the present invention, since the timer movement can be replaced, it not only enables the timer to realize different timing functions, but also saves maintenance costs.

Disclosed is a novel timer module. The novel timer module includes a replaceable movement 1, a master control circuit board 3, an upper housing 2, and a lower housing 6. A circuit board is disposed inside the replaceable movement 1. Five first inserting pins 11 are welded on the circuit board. Two of the five first inserting pins 11 are configured to input a power source for operating the circuit board of the replaceable movement 1, and the other three first inserting pins 11 are configured to control a relay inside the master control circuit board 3 to operate. The first inserting pins 11 are exposed from the outside of a housing 13 of the replaceable movement 1. The master control circuit board 3 is located in the upper housing 2 and the lower housing 6, and fixed on an upper surface of the lower housing 6. The relay is disposed inside the master control circuit board 3. A common terminal contact (COM), a normally open contact (NO) and a normally closed contact (NC) of the relay respectively extend and are fixed on a surface of the master control circuit board 3 by using leads. Three second inserting pins 31 are respectively welded on a loop of a control circuit portion (that is, a coil power supply) of the relay on the master control circuit board 3. Ends of the three second inserting pins 31 away from the master control circuit board 3 are connected to inserting slots 32. A null line and a live wire of a power supply circuit on the master control circuit board 3 further extend and are fixed on a surface of the master control circuit board 3 by using leads. The two second inserting pins 31 are respectively welded on the null line and the live wire of the power supply circuit on the master control circuit board 3. Ends of the two second inserting pins 31 away from the master control circuit board 3 are connected to the inserting slots 32. The two first inserting pins 11 configured to supply power are inserted into the two inserting slots 32 connected to the live wire and the null line. The three first inserting pins 11 configured to control the relay inside the master control circuit board 3 to operate are inserted into the three inserting slots 32 connected on the loop of the control circuit portion (that is, the coil power supply) of the relay.

Further, the five first inserting pins 11 of the replaceable movement 1 are distributed on a same straight line. Two of the five first inserting pins 11 configured to supply power are distributed adjacently. Three of the five first inserting pins 11 configured to control the relay inside the master control circuit board 3 to operate are distributed adjacently.

Further, the inserting slot 32 is disposed between two clamping clastic pieces 326. An opening of the inserting slot 32 faces upwards. The first inserting pin 11 of the replaceable movement 1 is a rectangular sheet. Through the adoption of such a structure, the first inserting pin 11 can be successively inserted into the inserting slot 32.

Further, a plurality of selection jumper wires 5 are disposed on the master control circuit board 3. According to actual use requirements of a user, one of the selection jumper wires 5 may be selected to connect to the circuit board of the corresponding replaceable movement 1.

Preferably, three selection jumper wires 5 respectively are a first selection jumper wire 51, a second selection jumper wire 52 and a third selection jumper wire 53. The first selection jumper wire 51 is configured to be connected to a circuit board of an intelligent movement. The second selection jumper wire 52 is configured to be connected to a circuit board of a conventional electronic movement. The third selection jumper wire is configured to be connected to a circuit board of a conventional mechanical movement.

Further, one or more crimping terminals 33 are welded on the master control circuit board 3. An L-shaped connecting copper sheet 4 penetrates into the crimping terminal 33. An end of the L-shaped connecting copper sheet 4 is welded on the surface of the master control circuit board 3.

Further, a top of the crimping terminal 33 is fixed inside a threaded hole 22 of the upper housing 2 by using a bolt 34.

Further, the upper housing 2 is provided with a connecting terminal inserting hole 23. A position of the crimping terminal 33 is mated with the connecting terminal inserting hole 23, to cause an external load connecting wire to be inserted into the crimping terminal 33 through the connecting terminal inserting hole 23 so as to conduct to the L-shaped connecting copper sheet 4.

Further, the plurality of crimping terminals 33 are distributed in a row, and a distance between the crimping terminals 33 is equal.

Further, two positioning pins 21 are disposed on the upper housing 2 and respectively are a first positioning pin 211 and a second positioning pin 212. The first positioning pin 211 and the second positioning pin 212 are configured to fix a plastic piece. The plastic piece covers the threaded hole 22 and the connecting terminal inserting hole 23 in a surface of the upper housing 2.

Further, a fixing device on an upper surface of the lower housing 6 is a screw post 61, and there may have one or more screw posts 61.

Further, the upper housing 2 can be fixedly connected to the lower housing 6 by conventional manners such as nuts and screws, guiding pipes and guiding posts or snaps.

An operating principle of the novel timer module of the present invention includes the following. The first inserting pin 11 of the replaceable movement 1 is connected to the inserting slot 32 in the master control circuit board 3, so that the replaceable movement I can control the on and off of the relay inside the master control circuit board 3. An external load with large power is connected to the master control circuit board 3 through the connecting terminal inserting hole 23, so that the master control circuit board 3 can control the operation of the load. The replaceable movement 1 of the present invention adopts a conventional timer control movement on the market. The master control circuit board 3 adopts a circuit board of a conventional timer controller. Therefore, the adoption of the novel timer module of the present invention can not only realize the change of a timing control mode, but also reduce a maintenance cost as the movement can be replaced. Under normal conditions, the damage to the conventional timer movement is usually the damage of the timer control portion, which may be damaged in about a year, while the relay control portion is very stable and can maintain a service life span of at least 10 years.

### BRIEF DESCRIPTION OF THE DRAWINGS

FIG. 1 is a schematic structural diagram of a timer module according to the present invention.

FIG. 2 is an explosive view of a timer module according to the present invention.

FIG. 3 is a schematic diagram of a timer module removing a replaceable movement.

FIG. 4 is a top view of a timer module removing a replaceable movement.

FIG. 5 is a schematic structural diagram of a master control circuit board.

FIG. 6 is a schematic structural diagram of a master control circuit board.

FIG. 7 is a schematic structural diagram of a master control circuit board.

FIG. 8 is a schematic structural diagram of a master control circuit board disposed in an upper housing.

FIG. 9 is an explosive view of a timer module according to the present invention.

FIG. 10 is a schematic structural diagram of a connecting copper sheet.

Reference of main elements in the drawings:

| | |
|---|---|
| Replaceable movement | 1 |
| First inserting pin | 11 |
| Housing | 13 |
| Upper housing | 2 |
| Positioning pin | 21 |
| First positioning pin | 211 |
| Second positioning pin | 212 |
| Threaded hole | 22 |
| Connecting terminal inserting hole | 23 |
| Master control circuit board | 3 |
| Second inserting pin | 31 |
| Inserting slot | 32 |
| First inserting slot | 321 |
| Second inserting slot | 322 |
| Third inserting slot | 323 |
| Fourth inserting slot | 324 |
| Fifth inserting slot | 325 |
| Clamping elastic piece | 326 |
| Crimping terminal | 33 |
| Bolt | 34 |
| Connecting copper sheet | 4 |
| Selection jumper wire | 5 |
| First selection jumper wire | 51 |
| Second selection jumper wire | 52 |
| Third selection jumper wire | 53 |
| Lower housing | 6 |
| Screw post | 61 |

The following specific implementations will further describe the utility model with reference to the above drawings.

### DETAILED DESCRIPTION OF THE EMBODIMENTS

### Specific Implementation 1

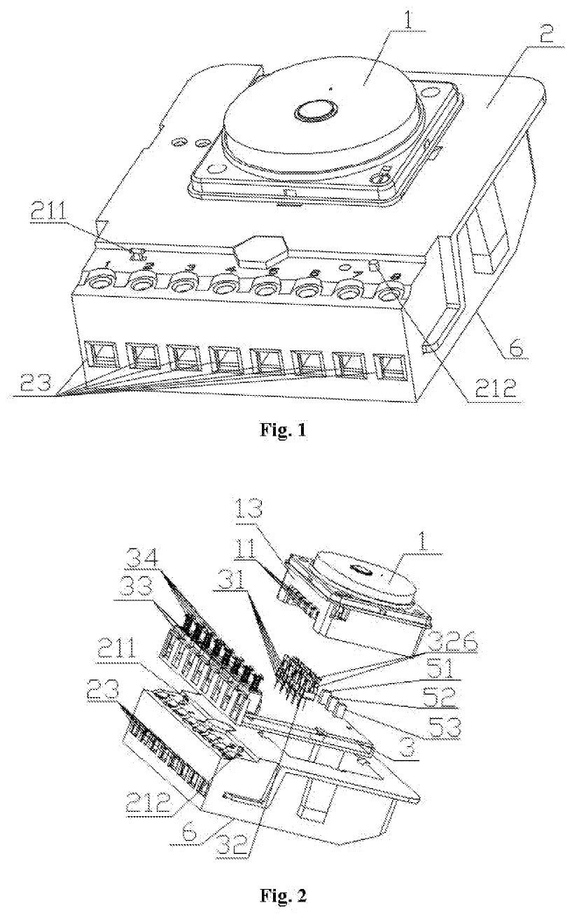

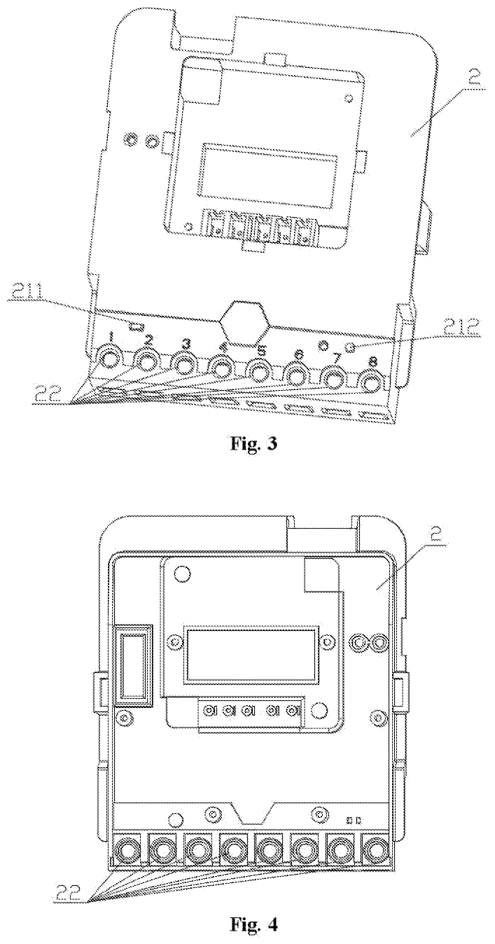

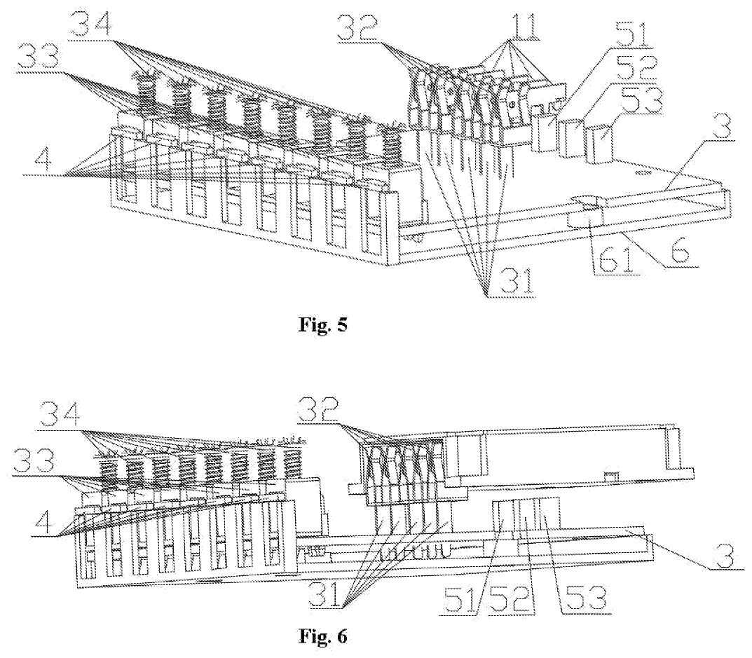

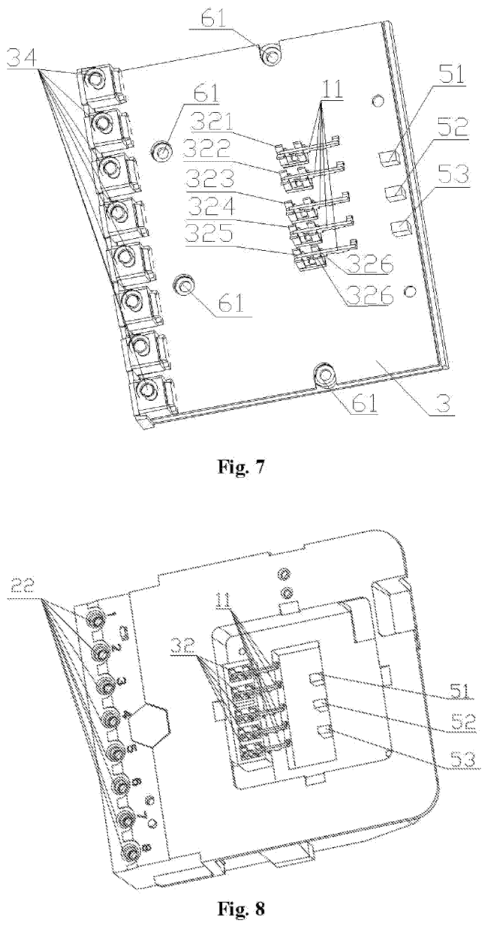

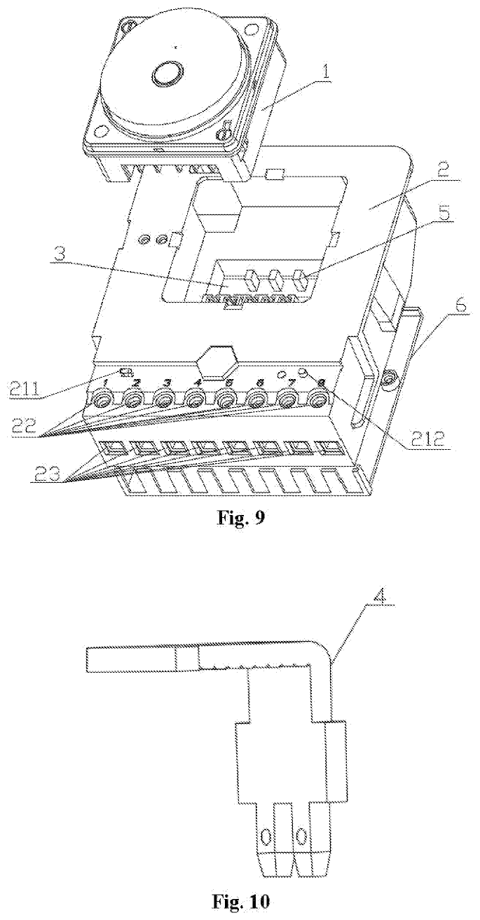

FIG. 1 is a schematic structural diagram of a timer module according to the present invention. FIG. 2 and FIG. 9 are explosive views of a timer module according to the present invention. FIG. 3 is a schematic diagram of a timer module removing a replaceable movement. FIG. 4 is a top view of a timer module removing a replaceable movement. FIGS. 5 to 7 are schematic structural diagrams of a master control circuit board. FIG. 8 is a schematic structural diagram of a master control circuit board disposed in an upper housing. FIG. 10 is a schematic structural diagram of a connecting copper sheet.

Disclosed is a novel timer module. The novel timer module includes a replaceable movement 1, a master control circuit board 3, an upper housing 2, and a lower housing 6. A circuit board is disposed inside the replaceable movement 1. Five first inserting pins 11 are welded on the circuit board. Two of the five first inserting pins 11 are configured to input a power source for operating the circuit board of the replaceable movement 1, and the other three first inserting pins 11 are configured to control a relay inside the master control circuit board 3 to operate. The first inserting pins 11 are exposed from the outside of a housing 13 of the replaceable movement 1. The master control circuit board 3 is located in the upper housing 2 and the lower housing 6, and fixed on an upper surface of the lower housing 6.

The relay is disposed inside the master control circuit board 3. A common terminal contact (COM), a normally open contact (NO) and a normally closed contact (NC) of the relay respectively extend and are fixed on a surface of the master control circuit board 3 by using leads. Three second inserting pins 31 are respectively welded on a loop of a control circuit portion (that is, a coil power supply) of the relay on the master control circuit board 3. Ends of the three second inserting pins 31 away from the master control circuit board 3 are connected to inserting slots 32. A null line and a live wire of a power supply circuit on the master control circuit board 3 further extend and are fixed on a surface of the master control circuit board 3 by using leads. The two second inserting pins 31 are respectively welded on the null line and the live wire of the power supply circuit on the master control circuit board 3. Ends of the two second inserting pins 31 away from the master control circuit board 3 are connected to the inserting slots 32. Five inserting slots 32 are arranged side by side, which respectively are a first inserting slot 321, a second inserting slot 322, a third inserting slot 323, a fourth inserting slot 324 and a fifth inserting slot 325. The first inserting slot 321 and the second inserting slot 322 are adjacently distributed. Two first inserting pins 11 configured to supply power are inserted into the first inserting slot 321 and the second inserting slot 322 that are connected to the live wire and the null line on the master control circuit board 3. The third inserting slot 323, the fourth inserting slot 324 and the fifth inserting slot 325 are adjacently distributed. Three first inserting pins 11 configured to control the relay inside the master control circuit board 3 to operate are inserted into the three inserting slots 32 connected to the loop of the control circuit portion (that is, the coil power supply) of the relay. That is to say, the three first inserting pins 11 are respectively inserted into the third inserting slot 323, the fourth inserting slot 324 and the fifth inserting slot 325.

The five first inserting pins 11 of the replaceable movement 1 are distributed on a same straight line. Two of the five first inserting pins 11 configured to supply power are distributed adjacently. Three of the five first inserting pins 11 configured to control the relay inside the master control circuit board 3 to operate are distributed adjacently.

The inserting slot 32 is disposed between two clamping clastic pieces 326. An opening of the inserting slot 32 faces upwards. The first inserting pin 11 of the replaceable movement 1 is a rectangular sheet. Through the adoption of such a structure, the first inserting pin 11 can be successively inserted into the inserting slot 32. The first inserting pin 11 is clamped by using the clamping clastic pieces 326, so that the first inserting pin 11 can be guaranteed to conduct with the second inserting pin 31.

A plurality of selection jumper wires 5 are disposed on the master control circuit board 3. According to actual use requirements of a user, the selection jumper wires 5 are selected to connect to the circuit board of the corresponding replaceable movement 1. Three selection jumper wires 5 respectively are a first selection jumper wire 51, a second selection jumper wire 52 and a third selection jumper wire 53. The first selection jumper wire 51 is configured to be connected to a circuit board of an intelligent movement. The second selection jumper wire 52 is configured to be connected to a circuit board of a conventional electronic movement. The third selection jumper wire 53 is configured to be connected to a circuit board of a conventional mechanical movement. By selecting different selection jumper wires 5, a timing function of a timer can be changed.

One or more crimping terminals 33 are welded on the master control circuit board 3. An L-shaped connecting copper sheet 4 penetrates into the crimping terminal 33. An end of the L-shaped connecting copper sheet 4 is welded on the surface of the master control circuit board 3.

A top of the crimping terminal 33 is fixed inside a threaded hole 22 of the upper housing 2 by using a bolt 34. The upper housing 2 is provided with a connecting terminal inserting hole 23. A position of the crimping terminal 33 is mated with the connecting terminal inserting hole 23, to cause an external load connecting wire to be inserted into the crimping terminal 33 through the connecting terminal inserting hole 23 so as to conduct to the L-shaped connecting copper sheet 4. Therefore, an external load with large power is connected to the master control circuit board 3 by using the connecting copper sheet 4, and the master control circuit board 3 can control the operation of the external load.

The plurality of crimping terminals 33 are distributed in a row, and a distance between the crimping terminals 33 is equal. Two positioning pins 21 are disposed on the upper housing 2 and respectively are a first positioning pin 211 and a second positioning pin 212. The first positioning pin 211 and the second positioning pin 211 are configured to fix a plastic piece. The plastic piece covers the threaded hole 22 and the connecting terminal inserting hole 23 in a surface of the upper housing 2.

A fixing device on an upper surface of the lower housing 6 is a screw post 61, and there may have one or more screw posts 61. The upper housing 2 can be fixedly connected to the lower housing 6 by conventional manners such as nuts and screws, guiding pipes and guiding posts or snaps.

An operating principle of the novel timer module of the present invention includes the following. The first inserting pin 11 of the replaceable movement 1 is connected to the inserting slot 32 in the master control circuit board 3, so that the replaceable movement 1 can control the on and off of the relay inside the master control circuit board 3. An external load with large power is connected to the master control circuit board 3 through the connecting terminal inserting hole 23, so that the master control circuit board 3 can control the operation of the load. The replaceable movement 1 of the present invention adopts a conventional timer control movement on the market. The master control circuit board 3 adopts a circuit board of a conventional timer controller. Therefore, the adoption of the novel timer module of the present invention can not only realize the change of a timing control mode, but also reduce a maintenance cost as the movement can be replaced. Under normal conditions, the damage to the conventional timer movement is usually the damage of the timer control portion, which may be damaged in about a year, while the relay control portion is very stable and can maintain a service life span of at least 10 years.

The above embodiments merely illustrate several implementations of the utility model, which are specifically described in detail, but are not to be construed as limiting the scope of the utility model patent. It should be noted that those ordinary skill in the art may also make several improvements and refinements without departing from the principle of the utility model, and these improvements and refinements shall fall within the protection scope of the utility model. Therefore, the protection scope of the utility model patent shall be subject to the appended claims.

What is claimed is:

1. A novel timer module, comprising a replaceable movement (1), a master control circuit board (3), an upper housing (2), and a lower housing (6), wherein a circuit board is disposed inside the replaceable movement (1), five first inserting pins (11) are welded on the circuit board, two of the five first inserting pins (11) are configured to input a power source for operating the circuit board of the replaceable movement (1), and the other three first inserting pins (11) are configured to control a relay inside the master control circuit board (3) to operate; the first inserting pins (11) are exposed from the outside of a housing (13) of the replaceable movement (1), the master control circuit board (3) is located in the upper housing (2) and the lower housing (6) and fixed on an upper surface of the lower housing (6), the relay is disposed inside the master control circuit board (3), a common terminal contact, a normally open contact and a normally closed contact of the relay respectively extend and are fixed on a surface of the master control circuit board (3) by using leads, three second inserting pins (31) are respectively welded on a loop of a control circuit portion of the relay on the master control circuit board (3), and ends of the three second inserting pins (31) away from the master control circuit board (3) are connected to inserting slots (32); a null line and a live wire of a power supply circuit on the master control circuit board (3) further extend and are fixed on a surface of the master control circuit board (3) by using leads, the two second inserting pins (31) are respectively welded on the null line and the live wire of the power supply circuit on the master control circuit board (3), and ends of the two second inserting pins (31) away from the master control circuit board (3) are connected to the inserting slots (32); and the two first inserting pins (11) configured to supply power are inserted into the two inserting slots (32) connected to the live wire and the null line, and the three first inserting pins (11) configured to control the relay to operate are inserted into the three inserting slots (32) connected on the loop of the control circuit portion of the relay.

2. The novel timer module as claimed in claim 1, wherein the five first inserting pins (11) of the replaceable movement (1) are distributed on a same straight line, two of the five first inserting pins (11) configured to supply power are distributed adjacently, and three of the five first inserting pins (11) configured to control the relay inside the master control circuit board (3) to operate are distributed adjacently.

3. The novel timer module as claimed in claim 1, wherein the inserting slot (32) is disposed between two clamping elastic pieces (326), an opening of the inserting slot (32) faces upwards, and the first inserting pin (11) of the replaceable movement (1) is a rectangular sheet.

4. The novel timer module as claimed in claim 1, wherein a plurality of selection jumper wires (5) are disposed on the master control circuit board (3), and one of the selection jumper wires (5) is connected to the circuit board of the corresponding replaceable movement (1).

5. The novel timer module as claimed in claim 4, wherein three selection jumper wires (5) respectively are a first selection jumper wire (51), a second selection jumper wire (52) and a third selection jumper wire (53), the first selection jumper wire (51) is configured to be connected to a circuit board of an intelligent movement, the second selection jumper wire (52) is configured to be connected to a circuit board of a conventional electronic movement, and the third selection jumper wire (53) is configured to be connected to a circuit board of a conventional mechanical movement.

6. The novel timer module as claimed in claim 4, wherein one or more crimping terminals (33) are welded on the master control circuit board (3), an L-shaped connecting copper sheet (4) penetrates into the crimping terminal (33), and an end of the L-shaped connecting copper sheet (4) is welded on a surface of the master control circuit board (3).

7. The novel timer module as claimed in claim 6, wherein a top of the crimping terminal (33) is fixed inside a threaded hole (22) of the upper housing (2) by using a bolt (34).

8. The novel timer module as claimed in claim 7, wherein the upper housing (2) is provided with a connecting terminal inserting hole (23), and a position of the crimping terminal (33) is mated with the connecting terminal inserting hole (23), to cause an external load connecting wire to be inserted into the crimping terminal (33) through the connecting terminal inserting hole (23) so as to conduct to the L-shaped connecting copper sheet (4).

9. The novel timer module as claimed in claim 6, wherein the plurality of crimping terminals (33) are distributed in a row, and a distance between the crimping terminals (33) is equal.

10. The novel timer module as claimed in claim 8, wherein two positioning pins (21) are disposed on the upper housing (2) and respectively are a first positioning pin (211) and a second positioning pin (212), the first positioning pin (211) and the second positioning pin (212) are configured to fix a plastic piece, and the plastic piece covers the threaded hole (22) and the connecting terminal inserting hole (23) in a surface of the upper housing (2).
